(19) United States
(12) Patent Application Publication
(10) Pub. No.: US 2024/0381752 A1
(43) Pub. Date: Nov. 14, 2024

(54) METAL OXIDE MATERIAL AND PREPARATION METHOD THEREFOR, AND OPTOELECTRONIC DEVICE

(71) Applicant: TCL TECHNOLOGY GROUP CORPORATION, Huizhou, Guangdong (CN)

(72) Inventor: Wei XU, Huizhou, Guangdong (CN)

(21) Appl. No.: 18/564,720

(22) PCT Filed: Sep. 19, 2022
(86) PCT No.: PCT/CN2022/119648

§ 371 Date: Nov. 28, 2023

(30) Foreign Application Priority Data
Sep. 30, 2021 (CN) 202111163473. X

(51) Int. Cl. H10K 71/15; H10K 50/115; H10K 50/155; H10K 50/165; H10K 71/30; H10K 85/60; H10K 102/00

(52) U.S. Cl. CPC H10K 71/15; H10K 50/115; H10K 50/155; H10K 50/165; H10K 71/30; H10K 85/60; H10K 2102/331

(57) ABSTRACT

The present disclosure discloses a metal oxide material and a preparation method therefor, and an optoelectronic device. The prepared metal oxide material comprises metal oxide nanoparticles, and on or both of halogenated acid ligands and halogenated alcohol ligands connected to the surfaces of the metal oxide nanoparticles. The ligands can effectively passivate defects of the metal oxide nanoparticles, thereby improving the luminous efficiency of the optoelectronic device and prolonging the service life of the optoelectronic device.

This disclosure claims priority of the Chinese patent disclosure with the Chinese Patent Application No. 202111163473.X, filed in the China National Intellectual Property Administration on Sep. 30, 2021, and entitled “METAL OXIDE MATERIAL AND PREPARATION METHOD THEREFOR, AND OPTOELECTRONIC DEVICE”, which is incorporated herein by reference in its entirety.

### TECHNICAL FIELD

The present disclosure relates to the field of display technologies, and more particularly, to a method for preparing a metal oxide material, a metal oxide material prepared by the method, and an optoelectronic device.

### BACKGROUND

QLED (Quantum Dots Light-Emitting Diode) is a new optoelectronic device, a structure of the QLED is similar to a structure of an OLED (Organic Light-Emitting Diode), and the QLED is a new technology between a liquid crystal and the OLED. A core technology of the QLED is quantum dots. The quantum dots are particles with a diameter less than 10 nm, which are mainly composed of zinc atom, cadmium atom, sulfur atom, and selenium atom. When quantum dots are stimulated by photoelectricity, they will emit colored light, and a color of the light is determined by materials that make up the quantum dots, and sizes and shapes of the quantum dots. A unique quantum size effect, a macroscopic quantum tunneling effect, a unique quantum size effect, and a surface effect of the quantum dot make itself exhibit excellent physical properties, especially optical properties, such as adjustable spectrum, high luminous intensity, high color purity, long fluorescence service life, and multi-color fluorescence excited by a single light source.

Nowadays, luminous efficiency of the QLED has reached the commercial demand basically. In addition, the service of the QLED is long, and packaging process is simple or even no need to be packaged, thereby it is expected to become the next generation flat panel display, and has broad development prospects.

One of main factors affecting a service life of an optoelectronic device is a carrier transmission efficiency of a carrier functional layer of the optoelectronic device.

### Technical Problems

Nowadays, a carrier transmission efficiency of metal oxide particles used to prepare the carrier functional layer is low.

### Technical Solutions

Therefore, the present disclosure provides a metal oxide material and a preparation method therefor, and an optoelectronic device.

Embodiments of the present disclosure provide a method for preparing a metal oxide material including steps as follows:
providing a metal salt solution, wherein the metal salt solution includes a metal salt;
adding a halogenated compound to the metal salt solution to obtain a precursor solution, wherein the halogenated compound is selected from one or both of a halogenated acid and a halogenated alcohol;
adding an alkali into the precursor solution and reacting to obtain a metal oxide material, wherein the metal oxide material includes a metal oxide nanoparticle and a halogenated ligand connected to a surface of the metal oxide nanoparticle, and the halogenated ligand include one or both of halogenated acid ligand and halogenated alcohol ligand.

Alternatively, a molar ratio of the metal salt to the halogenated compound ranges from 0.05:1 to 2:1.

Alternatively, the metal salt is selected from one or more of nickel salt, vanadium salt, titanium salt, tin salt, and zinc salt.

Alternatively, a concentration of the metal salt in the metal salt solution ranges from 0.067 mmol/mL to 133 mmol/mL.

Alternatively, a concentration of the metal salt in the metal salt solution ranges from 0.067 mmol/mL to 1 mmol/mL.

Alternatively, a molar ratio of the alkali to the metal salt ranges from 1:1 to 1:1.5.

Alternatively, the alkali is selected from one or more of potassium hydroxide, sodium hydroxide, and lithium hydroxide.

Alternatively, the halogenated acid is a halogenated acetic acid, and the halogenated alcohol is a halogenated ethanol.

Alternatively, the halogenated acetic acid is selected from one or more of monochlorinated acetic acid, dichlorinated acetic acid, trichlorinated acetic acid, trifluorinated acetic acid, and tribrominated acetic acid. The halogenated ethanol is selected from one or more of monochlorinated ethanol, dichlorinated ethanol, trichlorinated ethanol, trifluorinated ethanol, and tribrominated ethanol.

Alternatively, the reacting is carried out at a temperature ranging from 25° C. to 200° C.

Alternatively, a doped metal compound is further added to the metal salt solution. The doped metal compound is selected from one or more of a compound of copper, a compound of aluminum, a compound of tungsten, a compound of nickel, a compound of magnesium, a compound of titanium, a compound of tin, a compound of molybdenum, a compound of niobium, a compound of europium, a compound of zinc, a compound of manganese, a compound of zirconium, a compound of lithium, a compound of gallium, a compound of lanthanum, and a compound of ytterbium.

Alternatively, a molar ratio of the doped metal to the metal salt ranges from 1:19 to 1:4.

Alternatively, a doped metal element is doped in the metal oxide nanoparticle of the metal oxide material. The doped metal element is selected from one or more of Cu, Al, Wu, Ni, Mg, Ti, Sn, Mo, Nb, Eu, Zn, Mn, Zr, Li, Ga, La, and Yb. In the metal oxide material, a molar percentage content of the doped metal element ranges from 1% to 30%.

Correspondingly, the present disclosure further provides a metal oxide material, wherein the metal oxide material includes a metal oxide nanoparticle and a halogenated ligand connected to a surface of the metal oxide nanoparticle, the halogenated ligand includes one or both of halogenated acid ligand and halogenated alcohol ligand.

Alternatively, a halogenated acid of the halogenated acid ligand is a halogenated acetic acid, and a halogenated alcohol of the halogenated alcohol ligand is a halogenated ethanol. The halogenated acetic acid is selected from one or more of monochlorinated acetic acid, dichlorinated acetic acid, trichlorinated acetic acid, trifluorinated acetic acid, and tribrominated acetic acid. The halogenated ethanol is selected from one or more of monochlorinated ethanol, dichlorinated ethanol, trichlorinated ethanol, trifluorinated ethanol, and tribrominated ethanol.

Alternatively, in the metal oxide material, a content of the halogenated ligand ranges from 10 wt % to 50 wt %.

Alternatively, the metal oxide nanoparticle is selected from one or more of NiOₓ, VO_{y}, TiO₂, SnO₂, and ZnO, wherein the x is 1 or 1.5, and the y is 1, 1.5, 2, or 2.5.

Alternatively, a doped metal element is doped in the metal oxide nanoparticle of the metal oxide material.

Alternatively, the doped metal element is selected from one or more of Cu, Al, Wu, Ni, Mg, Ti, Sn, Mo, Nb, Eu, Zn, Mn, Zr, Li, Ga, La, and Yb.

Alternatively, in the metal oxide material, a molar percentage content of the doped metal element ranges from 1% to 30%.

Correspondingly, the present disclosure further provides an optoelectronic device including layers of an anode, a light-emitting layer, and a cathode. The optoelectronic device further includes at least one carrier functional layer, wherein each of the at least one carrier functional layer includes the metal oxide material prepared by the above method of preparing a metal oxide material.

Alternatively, the at least one carrier functional layer is a hole injection layer or a hole transport layer. The hole injection layer or the hole transport layer is disposed between the anode and the light-emitting layer. The metal oxide nanoparticle of the metal oxide material is selected from one or more of NiOₓ, and VO_{y}, wherein the x is 1 or 1.5, and the y is 1, 1.5, 2, or 2.5.

Alternatively, the at least one carrier functional layer is an electron transport layer, wherein the electron transport layer is disposed between the cathode and the light-emitting layer. The metal oxide nanoparticle of the metal oxide material is selected from one or more of ZnO, TiO₂, and SnO₂.

Alternatively, the light-emitting layer is an organic light-emitting layer or a quantum dot light-emitting layer. A material of the organic light-emitting layer is selected from one or more of 4, 4′-bis (N-carbazole)-1, 1′-biphenyl: tris [2-(p-tolyl) pyridin-C2, N) iridium (III), 4, 4′, 4′-tris (carbazol-9-yl) triphenylamine: tris [2-(p-tolyl) pyridin-C2, N) iridium (III), diaromatic anthracene derivative, aromatic stilbene derivative, pyrene derivative, fluorene derivative, TBPe fluorescent material, TTPA fluorescent material, TBRb fluorescent material, and DBP fluorescent material. A material of the quantum dot light-emitting layer is selected from one or more of a single quantum dot and a core-shell quantum dot. The single quantum dot is selected from one or more of group II-IV compound, group III-V compound, and group I-III-V compound. The group II-IV compound is selected from one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeTe, and CdZnSTe, the group III-V compound is selected from one or more of InP, InAs, GaP, GaAs, GaSb, AlN, AIP, InAsP, InNP, InNSb, GaAlNP, and InAINP, the group I-III-V compound is selected from one or more of CulnS₂, CuInSe₂, and AgInS₂. The core-shell quantum dot is selected from one or more of CdSe/ZnS, CdSe/ZnSe/ZnS, ZnCdSe/ZnSe/ZnS, ZnSe/ZnS, ZnSeTe/ZnS, CdSe/CdZnSeS/ZnS, InP/ZnSe/ZnS, and InP/ZnSeS/ZnS.

### Advantageous Effects

In the present disclosure, the metal oxide material prepared by the method for preparing a metal oxide material includes the metal oxide nanoparticle and one or both of the halogenated acid ligand and the halogenated alcohol ligand connected to surfaces of the metal oxide nanoparticle. The halogenated acid ligand and the halogenated alcohol ligand can passivate the defect state luminescence of the metal oxide nanoparticle effectively, thereby improving the dispersion and stability of the metal oxide nanoparticle in the solvent, improving the carrier transmission efficiency of the metal oxide nanoparticle, improving the carrier transport capability of the optoelectronic device, thereby improving the charge balance of the optoelectronic device, and further improving the luminous efficiency and service life of the optoelectronic device.

### BRIEF DESCRIPTION OF FIGURES

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a flowchart showing a method for preparing a metal oxide material according to an embodiment of the present disclosure.

FIG. 2 is a structure schematic diagram of an optoelectronic device according to an embodiment of the present disclosure.

FIG. 3 is a structure schematic diagram of another optoelectronic device according to an embodiment of the present disclosure.

FIG. 4 is a structure schematic diagram of another optoelectronic device according to an embodiment of the present disclosure.

FIG. 5 is a structure schematic diagram of another optoelectronic device according to an embodiment of the present disclosure.

FIG. 6 is a structure schematic diagram of another optoelectronic device according to an embodiment of the present disclosure.

### EMBODIMENTS OF THE PRESENT DISCLOSURE

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

The embodiments of the present disclosure provide a metal oxide material and a preparation method therefor, and an optoelectronic device. Detailed description is given below. It should be noted that the order in which the following embodiments are described is not intended to limit the preferred order of the embodiments. Additionally, in the description of the present disclosure, the term “comprising/including” means “comprising/including but not limited to.”

In the present disclosure, the terms “at least one” or “one or more” refer to one or more, and “a plurality of/multiple” refers to two or more. The terms “at least one”, “at least one of the followings”, or the like, refer to any combination of the items listed, including any combination of a single item or a plurality of items. For example, “at least one of a, b, or c” or “at least one of a, b, and c” may refer to: a, b, c, a-b (i.e., a and b), a-c, b-c, or a-b-c, where a, b, and c may be single or plural (multiple).

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For Embodiment, it should be considered that a description of a range from 1 to 6 has specifically disclosed su-branges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

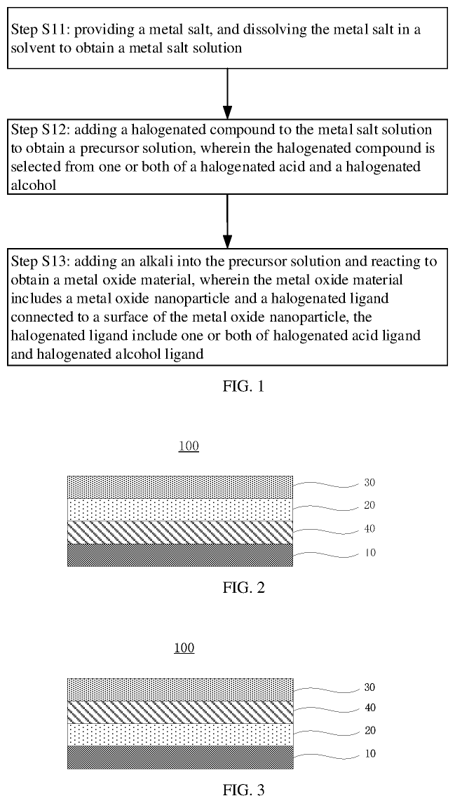

Referring to FIG. 1, the present disclosure provides a method for preparing a metal oxide material including steps as follows:
Step S11: providing a metal salt, and dissolving the metal salt in a solvent to obtain a metal salt solution;
Step S12: adding a halogenated compound to the metal salt solution to obtain a precursor solution, wherein the halogenated compound is selected from one or both of a halogenated acid and a halogenated alcohol;
Step S13: adding an alkali into the precursor solution and reacting to obtain a metal oxide material, wherein the metal oxide material includes a metal oxide nanoparticle and a halogenated ligand connected to a surface of the metal oxide nanoparticle, the halogenated ligand include one or both of halogenated acid ligand and halogenated alcohol ligand.

In the step S11 above:

A concentration of the metal salt in the metal salt solution ranges from 0.067 mmol/mL to 133 mmol/mL, for example, from 0.067 mmol/mL to 1 mmol/mL, and from 1 mmol/mL to 133 mmol/mL, etc., If a concentration of the metal salt solution is too low, the preparation efficiency is low, and the output of the metal oxide material is low. If the concentration of the metal salt solution is too high, the metal salt solution is difficult to be prepared, and the solubility of the metal salt solution to the one or both of the halogenated acid and the halogenated alcohol is low.

The solvent may be an organic solvent or water, for example, the solvent may be selected from but not limited to one or more of ethanol, propanol, butanol, amyl alcohol, ethylene glycol, 1-octadecanol, and water.

The metal salt may be selected from but not limited to one or more of nickel salt, vanadium salt, titanium salt, tin salt, and zinc salt.

The nickel salt may be selected from but not limited to one or more of nickel nitrate, nickel sulfate, nickel chloride, nickel fluoride, nickel bromide, and nickel iodide. It can be understood that, the nickel salt can be an anhydrous nickel salt or a hydrated nickel salt. For example, the nickel salt may be selected from but not limited to one or more of Ni(NO₃)₂, Ni(NO₃)₂·nH₂O, Ni(NO₃)₂, Ni(NO₃)₂·nH₂O, NiCl₂, NiCl₂·nH₂O, NiF₂, NiF₂·nH₂O, NiBr₂, NiBr₂·nH₂O, NiI₂, and NiI₂·nH₂O. Wherein the n is a number greater than 0.

The vanadium salt may be selected from but not limited to one or more of vanadium nitrate and vanadium sulfate. It can be understood that, the vanadium salt can be an anhydrous vanadium salt or a hydrated vanadium salt.

The titanium salt may be selected from but not limited to one or more of titanium nitrate, titanium sulfate, and titanium chloride. It can be understood that, the titanium salt can be an anhydrous titanium salt or a hydrated titanium salt.

The tin salt may be selected from but not limited to one or more of tin chloride, tin fluoride, tin bromide and tin iodide. It can be understood that, the tin salt can be an anhydrous tin salt or a hydrated tin salt. For example, the tin salt may be selected from but not limited to one or more of SnCl₄, SnCl₄·mH₂O, SnF+, SnF₄·mH₂O, SnBr₄, SnBr₄·mH₂O, SnI₄, and SnI₄·mH₂O. Wherein the m is a number greater than 0.

The zinc salt may be selected from but not limited to one or more of zinc acetate, zinc nitrate, zinc sulfate, zinc chloride, zinc fluoride, zinc bromide, and zinc iodide. It can be understood that, the zinc salt can be can be an anhydrous zinc salt or a hydrated zinc salt.

In the step S12 above:

The halogenated acid refers to a compound containing both halogen atom and carboxyl group in the molecule. The halogen atom may be but not limited to one or more of fluorine (F), chlorine (Cl), bromine (Br), and iodine (I). In some embodiments, the halogenated acid is a halogenated acetic acid, for example, the halogenated acid is selected from one or more of monochlorinated acetic acid (CH₂ClCOOH), dichlorinated acetic acid (CHCl₂COOH), trichlorinated acetic acid (CCl₃COOH), trifluorinated acetic acid (CF₃COOH), and tribrominated acetic acid (CBr₃COOH).

The halogenated alcohol refers to a compound containing both halogen atom and —CH₂—OH group in the molecule. The halogen atom may be but not limited to one or more of fluorine (F), chlorine (Cl), bromine (Br) and iodine (I). In some embodiments, the halogenated alcohol is a halogenated ethanol, for example, the halogenated alcohol is selected from one or more of monochlorinated ethanol (CH₂ClCH₂OH), dichlorinated ethanol (CHCl₂CH₂OH), trichlorinated ethanol (CCl₃CH₂OH), trifluorinated ethanol (CF₃COOH), and tribrominated ethanol (CBr₃COOH).

In some embodiments, a molar ratio of the metal salt to the halogenated compound ranges from 0.05:1 to 2:1.

In the step S13 above:

The alkali is a strong alkali. The strong alkali may be selected from but not limited to one or more of potassium hydroxide, sodium hydroxide, and lithium hydroxide. A molar ratio of the alkali to the metal salt ranges from 1:1 to 1:1.5. In some embodiments, the alkali added in the step S13 is an alcohol solution of the strong alkali, a concentration of the alcohol solution of the strong alkali may ranges from 6.7 mmol/mL to 133 mmol/mL.

In some embodiments, the reaction may be carried out at room temperature. It can be understood that, in other embodiments, the reaction may also be carried out under a heating and/or stirring condition in order to improve reaction rate. It can be understood that, a temperature of the heating is lower than a boiling point of the organic solvent, so as to avoid the influence of the reaction caused by the rapid evaporation of the organic solvent. In some embodiments, the temperature of the heating ranges from 25° C. to 200° C. A time of the reaction ranges from 0.3 h to 15 h, it can be understood that, the time of the reaction is not limited to thereto, as long as the metal salt can be sufficiently reacted with the alkali, and one or both of the halogenated acid and the halogenated alcohol.

It can be understood that, the reacting may be carried out in an inert atmosphere to improve the reaction efficiency and the purity of the reaction product. An inter gas of the inert atmosphere may be an inter gas conventionally used for chemical reactions, for example, the inter gas may be selected from but not limited to one or more of nitrogen, argon, and helium.

It can be understood that, in some embodiments, after obtaining the metal oxide material, a step of cleaning the metal oxide material is further included. Specifically, dissolving the metal oxide material by a cleaning solvent, centrifuging for precipitation, repeating the step of dissolution-precipitating, and then drying. The cleaning solvent may be selected from but not limited to one or more of cyclohexane, ethanol, n-hexane, octane, and dimethyl sulfoxide. A temperature of the drying may range from 50° C. to 70° C.

In some embodiments, a method of dissolving the metal salt in the organic solvent is heating and/or stirring. The heating temperature is not limited as long as it is lower than the boiling point of the organic solvent.

The metal oxide nanoparticle may be selected from but not limited to one or more of NiOₓ, VO_{y}, TiO₂, SnO₂, and ZnO. Wherein the x may be 1 or 1.5, and the y may be 1, 1.5, 2 or 2.5.

In the metal oxide material, a content of one or both of the halogenated ligand ranges from 10 wt % to 50 wt %. If the content of the halogenated ligand is too low, the defect state luminescence of the metal oxide nanoparticle cannot be effectively passivated; if the content of the halogenated ligand is too high, the conductivity of the metal oxide nanoparticle will be too low.

A particle size of the metal oxide nanoparticle ranges from 6 nm to 20 nm. In the range of the particle size, the dispersibility and stability of the metal oxide material can be effectively improved.

In some embodiments, a doped metal compound is further added to the metal salt solution to provide a doped metal element, thus to have the metal oxide nanoparticle in the prepared metal oxide material be doped with corresponding doped metal element, in other words, to have the metal oxide nanoparticle in the prepared metal oxide material are metal oxide nanoparticle doped with the metal element. The doped metal element can destroy the crystal lattice period of the metal oxide nanoparticle, to improve the free carrier concentration, and to improve a carrier mobility of the metal oxide nanoparticle.

In some embodiments, a molar ratio of the doped metal to the metal salt ranges from 1:19 to 1:4. If the content of the doped metal element is too low, there will be no doping effect. If the content of the doped metal element is too high, the doped metal element may crystallize and separate out independently.

The doped metal compound is selected from one or more of a compound of copper, a compound of aluminum, a compound of tungsten, a compound of nickel, a compound of magnesium, a compound of titanium, a compound of tin, a compound of molybdenum, a compound of niobium, a compound of europium, a compound of zinc, a compound of manganese, a compound of zirconium, a compound of lithium, a compound of gallium, a compound of lanthanum, and a compound of ytterbium. Correspondingly, the doped metal element of the metal oxide particle can be selected from but not limited to one or more of Cu, Al, Wu, Ni, Mg, Ti, Sn, Mo, Nb, Eu, Zn, Mn, Zr, Li, Ga, La, and Yb.

For examples, the doped metal compound can be selected from but not limited to one or more of Cu(NO₃)₂, Cu(NO₃)₂·5H₂O, Al(NO₃)₃, Al(NO₃)₃·9H₂O, WOCl₄, NiCl₂, MgCl₂, TiOCl₂, SnCl₂, MoCl₅, WCl₆, NbCl₅, TiCl₂, EuCl₃, ZnCl₂, magnesium acetate, manganese acetate, nickel acetate, zirconium acetate, lithium acetate, titanium acetate, gallium nitrate, lanthanum nitrate, and ytterbium nitrate. It can be understood that, the above-listed doped metal compounds are provided as examples, and are not limited thereto, as long as the corresponding doped metal element can be provided.

It can be understood that, when the metal salt is the nickel salt, the doped metal compound is not selected from the compound of nickel, and correspondingly, the doped metal element is not selected from Ni. When the metal salt is the titanium salt, the doped metal compound is not selected from the compound of titanium, and correspondingly, the doped metal element is not selected from Ti. When the metal salt is the tin salt, the doped metal compound is not selected from the compound of tin, and correspondingly, the doped metal element is not selected from Sn. When the metal salt is the zinc salt, the doped metal compound is not selected from the compound of zinc, and correspondingly, the doped metal element is not selected from Zn.

In some embodiments, the metal salt is the nickel salt, the doped metal compound may be selected from but not limited to one or more of Cu(NO₃)₂, Cu(NO₃)₂·5H₂O, Al(NO₃)₃, and Al(NO₃)₃·9H₂O, and correspondingly, the doped metal element may be selected from but not limited to one or more of Cu and Al.

In some embodiments, the metal salt is the vanadium salt, the doped metal compound may be selected from but not limited to one or more of WOCl₄, NiCl₂, MgCl₂, and TiOCl₂, and correspondingly, the doped metal element may be selected from but not limited to one or more of W, Ni, Mg, and Ti.

In some embodiments, the metal salt is the titanium salt, the doped metal compound may be selected from but not limited to one or more of SnCl₂, MoCl₅, WCl₆, and NbCl₅, and correspondingly, the doped metal element may be selected from but not limited to one or more of Sn, Mo, W, and Nb.

In some embodiments, the metal salt is the tin salt, the doped metal compound may be selected from but not limited to one or more of TiCl₂, EuCl₃, and ZnCl₂, and correspondingly, the doped metal element may be selected from but not limited to one or more of Ti, Eu, and Zn.

In some embodiments, the metal salt is the zinc salt, the doped metal compound may be selected from but not limited to one or more of magnesium acetate, manganese acetate, nickel acetate, zirconium acetate, lithium acetate, titanium acetate, gallium nitrate, lanthanum nitrate, and ytterbium nitrate, and correspondingly, the doped metal element may be selected from but not limited to one or more of Mg, Mn, Ni, Zr, Li, Ti, Ga, La, and Ye.

In the metal oxide material, a molar percentage content of the doped metal element ranges from 1% to 30%. If the content of the doped metal element is too low, there will be no doping effect. If the content of the doped metal element is too high, the doped metal element may crystallize and separate out independently.

In some embodiments, the metal oxide nanoparticle of the metal oxide material is selected from one or more of NiOₓ, VO_{y}, TiO₂, and SnO₂, at this time, the mass percentage content of the doped metal ranges from 1% to 20%.

In another embodiment, the metal oxide nanoparticle of the metal oxide material is ZnO, at this time, the mass percentage content of the doped metal ranges from 1% to 30%.

The metal oxide material prepared by the method for preparing a metal oxide material includes the metal oxide nanoparticle and one or both of the halogenated acid ligand and the halogenated alcohol ligand connected to surfaces of the metal oxide nanoparticle. The one or both of the halogenated acid ligand and the halogenated alcohol ligand can passivate the defect state luminescence of the metal oxide nanoparticle effectively, thereby improving the dispersion and stability of the metal oxide nanoparticle in the solvent, improving a carrier transmission efficiency of a carrier functional film including the metal oxide material, improving the carrier transport capability of the optoelectronic device, thereby improving the charge balance of the optoelectronic device, and further improving the luminous efficiency and service life of the optoelectronic device

The embodiments of the present disclosure further provide a carrier functional film which is mainly used in an optoelectronic device 100. The carrier functional film includes the metal oxide material. The carrier functional film may be an electron transport film, a hole transport film, or a hole injection film.

In some embodiments, the metal oxide nanoparticle of the metal oxide material is selected from one or more of NiOₓ and VOₓ, and the carrier functional film is the hole transport film or the hole injection film.

In another embodiment, the metal oxide nanoparticle of the metal oxide material is selected from one or more of ZnO, TiO₂, and SnO₂, and the carrier functional film is the electron transport film.

The embodiments of the present disclosure further provide a method for preparing the carrier functional film including steps as follows:
Step S21: providing the metal oxide material;
Step S22: arranging the metal oxide material on a substrate to form a metal oxide material film, and to obtain the carrier functional film.

It can be understood that, a type of the substrate is not limited. In one embodiment, the substrate is an electrode substrate, which can be a conventional substrate such as glass, and the metal oxide material is deposited on the electrode. In another embodiment, the substrate includes stacked electrode and light-emitting layer, and the metal oxide material is arranged on the light-emitting layer.

In the step S22, the method of arranging the metal oxide material on the substrate can be a chemical method or a physical method. Wherein, the chemical method can be chemical vapor deposition method, continuous ion layer adsorption and reaction method, anodization method, electrodeposition method, and coprecipitation method, and so on. The physical method can be a physical vapor deposition method or a solution processing method. The physical vapor deposition method can be thermal evaporation method, electron beam evaporation method, magnetron sputtering method, multiple arc ion plating method, physical vapor deposition (PVD) method, atomic layer deposition (ALD) method, and pulsed laser deposition (PLD) method, and so on. The solution processing method can be spin coating method, printing method, inkjet printing method, blade coating method, screen printing method, dip-coating method, immersion method, spray coating method, roll coating method, casting method, slot-die coating method, and slot-die coating method, and so on.

In some embodiments, the method of depositing the metal oxide material on the substrate is a solution method. At this time, the metal oxide material needs to be dispersed by a dispersant to obtain a metal oxide material dispersion liquid, and then, the metal oxide material dispersion liquid is arranged on the substrate by the solution method.

The dispersant can be selected from but not limited to one or more of cyclohexane, tert-butyl alcohol, methanol, ethanol, butanol, pentanol, 2-(trifluoromethyl)-3-2-ethoxydodecafluorohexane (C₉H₅F₁₅O), methoxy-nonafluorobutane (C₄F₉OCH₃), 1-chloro-4-methoxybutane (C₅H₁₁ClO), and 2-bromo-1,1-diethoxyethane (C₆H₁₃BrO₂). In at least one embodiment, the dispersion liquid is the cyclohexane and the tert-butyl alcohol, and a volume ratio of the cyclohexane and the tert-butyl alcohol is 1:1.

Referring to FIGS. 2-6, the embodiments of the present disclosure further provide an optoelectronic device 100. The optoelectronic device 100 may be a solar cell, a photodetector, an organic light-emitting device (OLED), or a quantum dot light-emitting device (QLED). The optoelectronic device 100 includes an anode 10, a light-emitting layer 20, and a cathode 30 which are sequentially stacked. The optoelectronic device 100 further includes at least one carrier functional layer 40. The at least one carrier functional layer 40 is connected between the anode 10 and the light-emitting layer 20, and/or, the at least one carrier functional layer 40 is connected between the light-emitting layer 20 and the cathode 30. The carrier functional layer 40 comprises the metal oxide material, in other words, the carrier functional layer 40 is the carrier functional film.

It can be understood that, the carrier functional layer 40 can be a hole injection layer, a hole transport layer, or an electron transport layer.

Referring to FIG. 2, in one embodiment, the optoelectronic device 100 includes the anode 10, the carrier functional layer 40, the light-emitting layer 20, and the cathode 30 which are sequentially stacked. The carrier functional layer 40 is the hole injection layer or the hole transport layer.

Referring to FIG. 3, in another embodiment, the optoelectronic device 100 includes the anode 10, the light-emitting layer 20, the carrier functional layer 40, and the cathode 30 which are sequentially stacked. The carrier functional layer 40 is the electron transport layer.

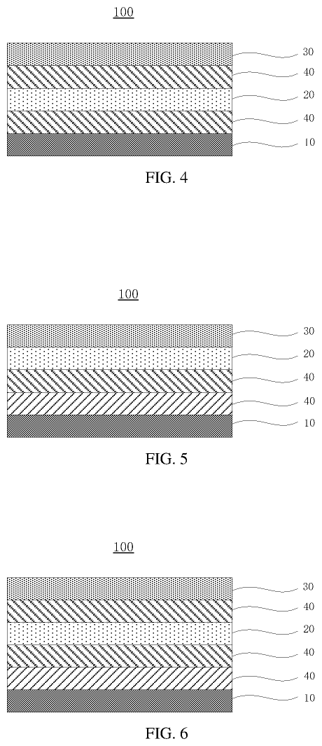

Referring to FIG. 4, in another embodiment, the optoelectronic device 100 includes the anode 10, the light-emitting layer 20, and the cathode 30 which are sequentially stacked. The optoelectronic device 100 further includes two carrier functional layers 40. One of the two carrier functional layers 40 is the hole injection layer or the hole transport layer, and is disposed between the anode 10 and the light-emitting layer 20. The other of the two carrier functional layers 40 is the electron transport layer, and is disposed between the light-emitting layer 20 and the cathode 30.

Referring to FIG. 5, in another embodiment, the optoelectronic device 100 includes the anode 10, the light-emitting layer 20, and the cathode 30 which are sequentially stacked. The optoelectronic device 100 further include two carrier functional layers 40. The two carrier functional layers 40 are sequentially stacked on the anode 10. The two carrier functional layers 40 are respectively the hole injection layer and the hole transport layer.

Referring to FIG. 6, in another embodiment, the optoelectronic device 100 includes the anode 10, the light-emitting layer 20, and the cathode 30 which are sequentially stacked. The optoelectronic device 100 further includes three carrier functional layers 40. Wherein, two of the three carrier functional layers 40 are sequentially stacked on the anode 10, and are respectively the hole injection layer and the hole transport layer. Another one of the three carrier functional layers 40 is disposed on the light-emitting layer 20, and is the electron transport layer.

In some embodiments, the carrier functional layer 40 is the hole injection layer or the hole transport layer, and the metal oxide nanoparticle of the metal oxide material are selected from one or more of NiOₓ, and VOₓ.

In another embodiment, the carrier functional layer 40 is the electron transport layer, and the metal oxide nanoparticle of the metal oxide material are selected from one or more of ZnO, TiO₂, and SnO₂.

A material of the anode 10 is a known material in the field for the anode, for example, the material of the anode 10 may be selected from but not limited to doped metal oxide electrode, composite electrode, etc., The doped metal oxide electrode may be selected from but not limited to one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), and aluminum-doped magnesium oxide (AMO). The composite electrode is a composite electrode with a metal layer sandwiched between doped or non-doped transparent metal oxide layers, such as AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, etc. Wherein, “/” represents a layered structure. For example, AZO/Ag/AZO represents a composite electrode with a layered structure formed by stacking AZO layer, Ag layer, and AZO layer sequentially.

The light-emitting layer 20 may be an organic light-emitting layer or a quantum dot light-emitting layer. When the light-emitting layer 20 is an organic light-emitting layer, the optoelectronic device 100 can be an organic optoelectronic device, for example, an organic electroluminescent device. When the light-emitting layer 20 is a quantum dot light-emitting layer, the optoelectronic device 100 can be a quantum dot electroluminescent device.

A material of the organic light-emitting layer is a known material in the field used for the organic light-emitting layer of the optoelectronic device. For example, the material of the organic light-emitting layer may be selected from but not limited to one or more of CBP:Ir(mppy)3 (4,4′-bis(N-carbazolyl)-1,1′-biphenyl: tris[2-(p-tolyl)pyridine-C2,N)iridium(III)]), TCTA:Ir(mmpy) (4,4′,4″-tris(carbazol-9-yl)triphenylamine: tris[2-(p-tolyl)pyridine-C2,N)iridium]), diaromatic anthracene derivative, aromatic stilbene derivative, pyrene derivative or fluorene derivative, blue-emitting TBPe fluorescent material, green-emitting TTPA fluorescent material, orange-emitting TBRb fluorescent material, and red-emitting DBP fluorescent material.

A material of the quantum dot light-emitting layer is a known quantum dot material in the field used for the quantum dot light-emitting layer of the optoelectronic device. For example, the quantum dot may be selected from but not limited to one or more of a single quantum dot and a core-shell quantum dot. For example, the quantum dot may be selected from but not limited to one or more of group II-IV compound, group III-V compound, and group I-III-V compound. As an example, the group II-IV compound may be selected from but not limited to one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeTe, and CdZnSTe. The group III-V compound may be selected from but not limited to one or more of InP, InAs, GaP, GaAs, GaSb, AlN, AIP, InAsP, InNP, InNSb, GaAlNP, and InAINP. The group I-III-V compound may be selected from but not limited to one or more of CuInS₂, CuInSe₂, and AgInS₂. The core-shell quantum dot may be selected from but not limited to one or more of CdSe/ZnS, CdSe/ZnSe/ZnS, ZnCdSe/ZnSe/ZnS, ZnSe/ZnS, ZnSeTe/ZnS, CdSe/CdZnSeS/ZnS, InP/ZnSe/ZnS, and InP/ZnSeS/ZnS.

A material of the cathode 30 is a known material in the field for the cathode of the optoelectronic device. For example, the material of the cathode 30 may be selected from but not limited to one or more of Ag electrode, Al electrode, Au electrode, Pt electrode, Ag/IZO electrode, IZO electrode, and alloy electrode.

It can be understood that, when the optoelectronic device 100 includes only one carrier functional layer 40, and the carrier functional layer 40 is the hole transport layer, the optoelectronic device 100 can further include an electron transport layer that does not include the metal oxide material, and/or, a hole injection layer that does not include the metal oxide material. A material of the electron transport layer that does not include the metal oxide material is a known material in the field for the electron transport layer, for example, the material of the electron transport layer that does not include the metal oxide material may be selected from one or more of ZnO, TiO₂, ZrO₂, HfO₂, Ca, Ba, CsF, LiF, CsCO₃, ZnMgO, PBD (2-(4-biphenyl)-5-phenyloxadiazole), 8-hydroxyquinoline aluminum (Alq3) and graphene. A material of the hole injection layer that does not include the metal oxide material is a known material in the field for the hole injection layer, for example, the material of the hole injection layer that does not include the metal oxide material may not of be selected from but limited to one or more 2,3,6,7,10,11-hexocyano-1,4,5,8,9,12-hexazabenzophenanthrene (HAT-CN), PEDOT: PSS and its derivative doped with s-MoO₃ (PEDOT: PSS: s-MOO₃).

It can be understood that, when the optoelectronic device 100 includes only one carrier functional layer 40, and the carrier functional layer 40 is the electron transport layer, the optoelectronic device 100 can further include a hole transport layer that does not include the metal oxide material, and/or, a hole injection layer that does not include the metal oxide material. A material of the hole transport layer that does not include the metal oxide material is a known material in the field for the hole transport layer, for example, the material of the hole transport layer that does not include the metal oxide material may be selected from but not limited to one or more of poly[bis(4-phenyl) (2,4,6-trimethylphenyl)amine] (PTAA), 2,2′,7,7′-tetrakis[N,N-di(4-methoxyphenyl)amino]-9,9′-spirobifluorene (spiro-OMeTAD), 4,4′-cyclohexylidenebis[N,N-bis(4-methylphenyl) aniline] (TAPC), N,N′-bis(1-naphthyl)-N,N′-diphenyl-1,1′-biphenyl-4,4′-diamine (NPB), (CBP), 4,4′-bis(N-carbazolyl)-1,1′-biphenyl poly[(9,9-dioctylfluorenyl-2,7-diyl)-co-(4,4′-(N-(p-butylphenyl))diphenylamine)] (TFB), poly(9-vinylcarbazole) (PVK), polytriphenylamine (Poly-TPD), poly(3,4-ethylenedioxythiophene)-poly(styrenesulfonate) (PEDOT:PSS), and 4,4′,4″-tris(carbazol-9-yl)triphenylamine (TCTA).

It can be understood that, in addition to the aforementioned functional layers, the optoelectronic device 100 may also include some functional layers which are commonly used in optoelectronic device to improve the performance of the optoelectronic device, for example an electron blocking layer, a hole blocking layer, an electron injection layer, an interface modification layer, and so on.

It can be understood that, a material of each layer of the optoelectronic device 100 can be adjusted according to the light emitting requirements of the optoelectronic device 100.

It can be understood that, the optoelectronic device 100 can be an upright optoelectronic device or an inverted optoelectronic device.

The embodiments of the present disclosure further provide a method for preparing the optoelectronic device 100 including steps as follows:
Step S31: providing an anode 10;
Step S32: forming a light-emitting layer 20 on the anode 10;
Step S33: forming a cathode 30 on the light-emitting layer 20.

The preparation method further includes: forming at least one carrier functional layer 40 on the anode 10, and/or, forming at least one carrier functional layer 40 on the light-emitting layer 20.

The embodiments of the present disclosure further provide another method for preparing the optoelectronic device 100 including steps as follows:
Step S41: providing a cathode 30;
Step S42: forming a light-emitting layer 20 on the cathode 30;
Step S43: forming an anode 10 on the light-emitting layer 20.

The preparation method further includes: forming at least one carrier functional layer 40 on the cathode 30, and/or, forming at least one carrier functional layer 40 on the light-emitting layer 20.

In the two preparation methods:

A method for preparing the at least one carrier functional layer 40 is the same as the method for preparing the carrier functional film, and will not be repeated here.

Methods for forming the anode 10, the light-emitting layer 20, the cathode layer 30, and the at least one carrier functional layer 40 may be implemented by conventional techniques in the art, for example, the chemical method or the physical method. The chemical method or the physical method is referred to above, and will not be repeated here.

It can be understood that, when the optoelectronic device 100 further includes other functional layers such as the electron blocking layer, the hole blocking layer, the electron injection layer, and/or the interface modification layer, the method for preparing the optoelectronic device 100 will further includes steps of forming the functional layers.

The present disclosure is described in detail below by way of specific embodiments, the specific embodiments are only partial embodiments of the present disclosure and are not limited to the present disclosure.

### Example 1

Providing a ITO anode 10 with a thickness of 20 nm;
spin-coating PEDOT: PSS (model AI4083) material on the anode 10, and then heat treating at 150° C. for 15 min to obtain a hole injection layer with a thickness of 35 nm;
dissolving 100 mmol NiOₓ in 100 mL ethanol, adding 0.08 mol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a nickel oxide nanoparticle and a tribrominated ethanol ligand connected on a surface of the nickel oxide nanoparticle, and a content of the tribrominated ethanol ligand is 30 wt %;
dispersing the metal oxide material in a mixed liquid of 150 mL tert-butyl alcohol and 150 mL cyclohexane to obtain a metal oxide material dispersion liquid with a concentration of 25 mg/mL, spin-coating the metal oxide material dispersion liquid on the hole injection layer, and then heat treating at 200° C. for 30 min to obtain a carrier functional layer 40 with a thickness of 20 nm, namely a hole transport layer;
spin-coating a quantum dot luminescent material of InP/ZnSe/ZnS on the carrier functional layer 40 to obtain a light-emitting layer 20 with a thickness of 30 nm;
spin-coating a ZnMgO material on the light-emitting layer 20, wherein a content of Mg in the ZnMgO material is 15 wt %, and then heat treating for 40 min in nitrogen atmosphere and at 80° C. to obtain an electron transport layer with a thickness of 50 nm;
evaporating Ag on the electron transport layer to obtain a cathode 30 with a thickness of 60 nm;
evaporating NPB material on the cathode 30 to obtain a covering layer with a thickness of 50 nm, thus to obtain an optoelectronic device 100. The optoelectronic device 100 of this example is a quantum dot electroluminescent device.

### Example 2

This example is basically the same as that of Example 1, the difference is that, this example uses dichlorinated acetic acid to replace tribrominated ethanol of Example 1. Correspondingly, the metal oxide material obtained in this example includes a nickel oxide nanoparticle and an adibrominated ethanol ligand connected to a surface of the nickel oxide nanoparticle.

### Example 3

This example is basically the same as that of Example 1, the difference is that, this example uses 0.04 mmol monochlorinated ethanol and 0.04 mmol trichlorinated acetic acid to replace 0.08 mmol tribrominated ethanol of Example 1. Correspondingly, the metal oxide material obtained in this example includes a nickel oxide nanoparticle and a monochlorinated ethanol ligand and a trichlorinated acetic acid ligand connected to a surface of the nickel oxide nanoparticle.

### Example 4

This example is basically the same as that of Example 1, the difference is that, in this example, dissolving 90 mmol Ni(NO₃)₂·6H₂O and 10 mmol Cu(NO₃)₂·5H₂O in 100 mL ethanol. Correspondingly, the metal oxide material obtained in this embodiment includes a nickel oxide nanoparticle doped with Cu and a tribrominated ethanol ligand connected to a surface of the nickel oxide nanoparticle doped with Cu.

### Example 5

This example is basically the same as that of Example 1, the difference is that, in this example, dissolving 90 mmol Ni(NO₃)₂·6H₂O, 5 mmol Cu(NO₃)₂·5H₂O and 5 mmol Al(NO₃)₃·9H₂O in 100 mL ethanol. Correspondingly, the metal oxide material obtained in this example includes a nickel oxide nanoparticle doped with Cu and Al and a tribrominated ethanol ligand connected to a surface of the nickel oxide nanoparticle doped with Cu and Al.

### Example 6

This example is basically the same as that of Example 1, the difference is that, in this example, a method for preparing the hole injection layer is:
dissolving 100 mmol NiOₓ in 100 mL ethanol, adding 0.08 mol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a nickel oxide nanoparticle and a tribrominated ethanol ligand connected to a surface of the nickel oxide nanoparticle, and a content of the tribrominated ethanol ligand is 30 wt %;
dispersing the metal oxide material in a mixed liquid of 150 mL tert-butyl alcohol and 150 mL cyclohexane to obtain a metal oxide material dispersion liquid with a concentration of 25 mg/mL, spin-coating the metal oxide material dispersion liquid on the anode 10, and then heat treating at 200° C. for 30 min to obtain a hole injection layer with a thickness of 20 nm, namely a carrier functional layer 40.

### Example 7

Providing a ITO anode 10 with a thickness of 20 nm;
dissolving 100 mmol NiOₓ in 100 mL ethanol, then adding 0.08 mol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a nickel oxide nanoparticle and a tribrominated ethanol ligand connected to a surface of the nickel oxide nanoparticle, and a content of the tribrominated ethanol ligand is 30 wt %;
dispersing the metal oxide material in a mixed liquid of 150 mL tert-butyl alcohol and 150 mL cyclohexane to obtain a metal oxide material dispersion liquid with a concentration of 25 mg/mL, spin-coating the metal oxide material dispersion liquid on the anode 10, and then heat treating at 200° C. for 30 min to obtain the hole injection layer with a thickness of 20 nm, namely a carrier functional layer 40;
spin-coating TFB material on the hole injection layer, and then heat treating for 15 min in nitrogen atmosphere and at 150° C. to obtain a carrier functional layer 40 with a thickness of 20 nm, namely a hole transport layer;
spin-coating CBP:Ir(mppy)3 material on the carrier functional layer 40 to obtain a light-emitting layer 20 with a thickness of 30 nm;
spin-coating PBD material on the light-emitting layer 20, and heat treating for 40 min in nitrogen atmosphere and at 150° C. to obtain an electron transport layer with a thickness of 50 nm;
evaporating Ag on the electron transport layer to obtain a cathode 30 with a thickness of 60 nm;
evaporating material of NPB on the cathode 30 to obtain a covering layer with a thickness of 50 nm, thus to obtain an optoelectronic device 100. The optoelectronic device 100 of this example is an organic electroluminescent device.

### Example 8

This example is basically the same as that of Example 1, the difference is that, in this example, a method of preparing the hole transport layer is:
dissolving 10 mmol vanadium nitrate in 200 mL 1-octadecanol, adding 10 mmol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a vanadium oxide nanoparticle and a tribrominated ethanol ligand connected to a surface of the vanadium oxide nanoparticle, and a content of the tribrominated ethanol ligand is 40 wt %;
dispersing the metal oxide material in methoxy-nonafluorobutane to obtain a metal oxide material dispersion liquid with a concentration of 25 mg/mL, spin-coating the metal oxide material dispersion liquid on the hole injection layer, and then heat treating at 200° C. for 30 min to obtain a hole transport layer with a thickness of 20 nm, namely a carrier functional layer 40.

### Example 9

This example is basically the same as that of Example 8, the difference is that, in this example, dissolving 10 mmol vanadium nitrate and 10 mmol WCl₆ in 200 mL 1-octadecanol. Correspondingly, the metal oxide material obtained in this example includes a vanadium oxide nanoparticle doped with Wu and a tribrominated ethanol ligand connected to a surface of the vanadium oxide nanoparticle doped with Wu.

### Example 10

This example is basically the same as that of Example 8, the difference is that, in this example, dissolving 10 mmol vanadium nitrate, 10 mmol WCl₆, and 5 mmol NiCl₂ in 200 mL 1-octadecanol. Correspondingly, the metal oxide material obtained in this example includes a vanadium oxide nanoparticle doped with Ni and a tribrominated ethanol ligand connected to a surface of the vanadium oxide nanoparticle doped with Ni.

### Example 11

This example is basically the same as that of Example 7, the difference is that, a method for preparing the hole injection layer of this example is:
dissolving 10 mmol vanadium nitrate in 200 mL 1-octadecanol, adding 10 mmol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a vanadium oxide nanoparticle and a tribrominated ethanol ligand connected to a surface of the vanadium oxide nanoparticle, and a content of the tribrominated ethanol ligand is 40 wt %;
dispersing the metal oxide material in methoxy-nonafluorobutane to obtain a metal oxide material dispersion liquid with a concentration of 25 mg/mL, spin-coating the metal oxide material dispersion liquid on the anode 10, and then heat treating at 200° C. for 30 min to obtain a hole injection layer with a thickness of 20 nm, namely a carrier functional layer 40.

### Example 12

This example is basically the same as that of Example 1, the difference is that, a method for preparing the hole transport layer and a method for preparing the electron transport layer of this example are:
spin-coating TFB material on the hole injection layer, and then heat treating at 150° C. for 15 min to obtain a hole transport layer with a thickness of 20 nm.
dissolving 10 mmol titanium chloride in 150 mL ethanol, adding 20 mmol tribromide ethanol, adding 10 mL potassium hydroxide solution with a concentration of 16.5 mol, heating and stirring for 3 hours in nitrogen atmosphere and at 60° C., and dissolving with cyclohexane and cleaning with centrifugal precipitation for 3 times to obtain a metal oxide material, wherein the metal oxide material includes a titanium dioxide nanoparticle and a tribrominated ethanol ligand connected to a surface of the titanium dioxide nanoparticle, and a content of the tribrominated ethanol ligand is 40 wt %;
dispersing the metal oxide material in methoxy-nonafluorobutane to obtain a metal oxide material dispersion liquid with a concentration of 25 mg/mL, spin-coating the metal oxide material dispersion liquid on the light-emitting layer 20, and then heat treating at 90° C. for 30 min to obtain an electron transport layer with a thickness of 50 nm.

### Example 13

This example is basically the same as that of Example 12, the difference is that, in this example, dissolving 9 mmol titanium chloride and 1 mmol SnCl₂ in 150 mL ethanol. Correspondingly, the metal oxide material obtained in this example includes a titanium dioxide nanoparticle doped with Sn and a tribrominated ethanol ligand connected to a surface of the titanium dioxide nanoparticle doped with Sn.

### Example 14

This example is basically the same as that of Example 7, the difference is that, a method for preparing the hole injection layer and a method for preparing the electron transport layer of this example are:
spin-coating PEDOT: PSS (model AI4083) material on the anode 10, and then heat treating at 150° C. for 15 min to obtain a hole injection layer with a thickness of 20 nm.
dissolving 10 mmol titanium chloride in 150 mL ethanol, adding 20 mmol tribromide ethanol, adding 10 mL potassium hydroxide solution with a concentration of 16.5 mol, heating and stirring for 3 hours in nitrogen atmosphere and at 60° C., and dissolving with cyclohexane and cleaning with centrifugal precipitation for 3 times to obtain a metal oxide material, wherein the metal oxide material includes a titanium dioxide nanoparticle and a tribrominated ethanol ligand connected to a surface of the titanium dioxide nanoparticle, and a content of the tribrominated ethanol ligand is 40 wt %;
dispersing the metal oxide material in methoxy-nonafluorobutane to obtain a metal oxide material dispersion liquid with a concentration of 25 mg/mL, spin-coating the metal oxide material dispersion liquid on the light-emitting layer 20, and then heat treating at 90° C. for 30 min to obtain an electron transport layer with a thickness of 50 nm.

### Example 15

This example is basically the same as that of Example 12, the difference is that, a method for preparing the electron transport layer of this example is:
dissolving 10 mmol SnCl₄·5H₂O in 200 mL ethanol, adding 50 mmol tribromide ethanol, adding 10 mL potassium hydroxide solution with a concentration of 16.5 mol, heating and stirring for 3 hours in nitrogen atmosphere and at 60° C., and dissolving with cyclohexane and cleaning with centrifugal precipitation for 3 times to obtain a metal oxide material, wherein the metal oxide material includes a tin oxide nanoparticle and a tribrominated ethanol ligand connected to a surfaces of the tin oxide nanoparticle, and a content of the tribrominated ethanol ligand is 50 wt %;
dispersing the metal oxide material in methoxy-nonafluorobutane to obtain a metal oxide material dispersion liquid with a concentration of 25 mg/mL, spin-coating the metal oxide material dispersion liquid on the light-emitting layer 20, and then heat treating at 90° C. for 30 min to obtain an electron transport layer with a thickness of 50 nm.

### Example 16

This example is basically the same as that of Example 15, the difference is that, in this example, dissolving 8 mmol titanium chloride, 1 mmol ZnCl₂, and 1 mmol EuCl₃ in 150 mL ethanol. Correspondingly, the metal oxide material obtained in this example includes a tin oxide nanoparticle doped with Zn and Eu and a tribrominated ethanol ligand connected to a surface of the tin dioxide nanoparticle doped with Zn and Eu.

### Example 17

This example is basically the same as that of Example 14, the difference is that, a method for preparing the electron transport layer of this example is:
dissolving 10 mmol SnCl₄·5H₂O in 200 mL ethanol, adding 50 mmol tribromide ethanol, adding 10 mL potassium hydroxide solution with a concentration of 16.5 mol, heating and stirring for 3 hours in nitrogen atmosphere and at 60° C., and dissolving with cyclohexane and cleaning with centrifugal precipitation for 3 times to obtain a metal oxide material, wherein the metal oxide material includes a tin oxide nanoparticle and a tribrominated ethanol ligand connected to a surface of the tin oxide nanoparticle, and a content of the tribrominated ethanol ligand is 50 wt %;
dispersing the metal oxide material in methoxy-nonafluorobutane to obtain a metal oxide material dispersion liquid with a concentration of 25 mg/mL, spin-coating the metal oxide material dispersion liquid on the light-emitting layer 20, and then heat treating at 90° C. for 30 min to obtain an electron transport layer with a thickness of 50 nm.

### Example 18

This example is basically the same as that of Example 12, the difference is that, a method for preparing the electron transport layer of this example is:
dissolving 15 mol zinc acetate in 150 mL ethanol, adding 100 mmol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a zinc oxide nanoparticle and a tribrominated ethanol ligand connected to a surface of the zinc oxide nanoparticle, and a content of the tribrominated ethanol ligand is 40 wt %;
dispersing the metal oxide material in methoxy-nonafluorobutane to obtain a metal oxide material dispersion liquid with a concentration of 25 mg/mL, spin-coating the metal oxide material dispersion liquid on the light-emitting layer 20, and then heat treating at 90° C. for 30 min to obtain an electron transport layer with a thickness of 50 nm.

### Example 19

This example is basically the same as that of Example 18, the difference is that, in this example, dissolving 8 mmol zinc acetate, 1 mmol magnesium acetate, and 1 mmol lithium acetate in 150 mL ethanol. Correspondingly, the metal oxide material obtained in this example includes a zinc oxide nanoparticle doped with Mg and Li and a tribrominated ethanol ligand connected to a surface of the zinc oxide nanoparticle doped with Mg and Li.

### Example 20

This example is basically the same as that of Example 14, the difference is that, a method for preparing the electron transport layer of this example is:
dissolving 15 mol zinc acetate in 150 mL ethanol, adding 100 mmol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a zinc oxide nanoparticle and a tribrominated ethanol ligand connected to a surface of the zinc oxide nanoparticle, and a content of the tribrominated ethanol ligand is 40 wt %;
dispersing the metal oxide material in methoxy-nonafluorobutane to obtain a metal oxide material dispersion liquid with a concentration of 25 mg/mL, spin-coating the metal oxide material dispersion liquid on the light-emitting layer 20, and then heat treating at 90° C. for 30 min to obtain an electron transport layer with a thickness of 50 nm.

### Example 21

This example is basically the same as that of Example 6, the difference is that, a method for preparing the electron transport layer of this example is:
dissolving 15 mol zinc acetate in 150 mL ethanol, adding 100 mmol tribromide ethanol, adding 10 mL potassium hydroxide solution with a concentration of 16.5 mol, heating and stirring at 60° C. for 3 hours, and dissolving with cyclohexane and cleaning with centrifugal precipitation for 3 times to obtain a metal oxide material, wherein the metal oxide material includes a zinc oxide nanoparticle and a tribrominated ethanol ligand connected to a surface of the zinc oxide nanoparticle, and a content of the tribrominated ethanol ligand is 40 wt %;
dispersing the metal oxide material in methoxy-nonafluorobutane to obtain a metal oxide material dispersion liquid with a concentration of 25 mg/mL, spin-coating the metal oxide material dispersion liquid on the light-emitting layer 20, and then heat treating at 90° C. for 30 min to obtain the electron transport layer with a thickness of 50 nm.

### Comparative Example 1

This Comparative Example is basically the same as that of Example 1, the difference is that, a material of the hole transport layer 22 is TFB.

### Comparative Example 2

This Comparative Example is basically the same as that of Example 7, the difference is that, a material of the hole injection layer 21 is PEDOT: PSS (model AI4083).

External quantum efficiency EQE and service life T95_1knit of the Examples 1-21 and Comparative Examples 1-2 were tested. Wherein, the External quantum efficiency EQE was tested by EQE optical testing instrument, the service life was tested by service life testing box. The service life T95_1knit refers to the time that the brightness of the quantum dot light emitting diode decays to 95% from an initial brightness of 1knit. The test results are shown in Table 1 below.

TABLE 1

| | External quantum | service life |
|---|---|---|
| | efficiency (EQE)/% | T95 1knit/h |
| Example 1 | 20 | 11000 |
| Example 2 | 16 | 13000 |
| Example 3 | 15 | 14000 |
| Example 4 | 18 | 13000 |
| Example 5 | 17 | 14000 |
| Example 6 | 19 | 16000 |
| Example 7 | 16 | 15000 |
| Example 8 | 18 | 17000 |
| Example 9 | 18 | 14000 |
| Example 10 | 20 | 15000 |
| Example 11 | 15 | 11000 |
| Example 12 | 16 | 12000 |
| Example 13 | 17 | 19000 |
| Example 14 | 18 | 20000 |
| Example 15 | 19 | 21000 |
| Example 16 | 17 | 16000 |
| Example 17 | 18 | 14000 |
| Example 18 | 19 | 22000 |
| Example 19 | 17 | 16000 |
| Example 20 | 18 | 18000 |
| Example 21 | 19 | 17000 |
| Comparative Example 1 | 10 | 5000 |
| Comparative Example 2 | 8 | 6000 |

As can be seen from Table 1, the External quantum efficiency and the service life of the optoelectronic devices in the Examples 1-21 are significantly higher than those of the optoelectronic devices in the Comparative Examples 1-2.

The method for preparing the metal oxide material and the metal oxide material prepared by the method according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

1. A method for preparing a metal oxide material, comprising:
providing a metal salt solution, wherein the metal salt solution comprises a metal salt;
adding a halogenated compound to the metal salt solution to obtain a precursor solution, wherein the halogenated compound is selected from one or both of a halogenated acid and a halogenated alcohol;
adding an alkali into the precursor solution and reacting to obtain a metal oxide material, wherein the metal oxide material comprises a metal oxide nanoparticle and a halogenated ligand connected to a surface of the metal oxide nanoparticle, the halogenated ligand comprises one or both of a halogenated acid ligand and a halogenated alcohol ligand.

2. The method according to claim 1, wherein a molar ratio of the metal salt to the halogenated compound ranges from 0.05:1 to 2:1.

3. The method according to claim 1, wherein the metal salt is selected from one or more of nickel salt, vanadium salt, titanium salt, tin salt, and zinc salt.

4. The method according to claim 1, wherein a concentration of the metal salt in the metal salt solution ranges from 0.067 mmol/mL to 133 mmol/mL.

5. The method according to claim 1, wherein a concentration of the metal salt in the metal salt solution ranges from 0.067 mmol/mL to 1 mmol/mL.

6. The method according to claim 1, wherein a molar ratio of the alkali to the metal salt ranges from 1:1 to 1:1.5.

7. The method according to claim 1, wherein the alkali is selected from one or more of potassium hydroxide, sodium hydroxide, and lithium hydroxide.

8. The method according to claim 1, wherein the halogenated acid is a halogenated acetic acid, the halogenated alcohol is a halogenated ethanol, the halogenated acetic acid is selected from one or more of monochlorinated acetic acid, dichlorinated acetic acid, trichlorinated acetic acid, trifluorinated acetic acid, and tribrominated acetic acid, and the halogenated ethanol is selected from one or more of monochlorinated ethanol, dichlorinated ethanol, trichlorinated ethanol, trifluorinated ethanol, and tribrominated ethanol.

9. The method according to claim 1, wherein the reacting is carried out at a temperature ranging from 25° C. to 200° C.

10. The method according to claim 1, wherein a doped metal compound is further added to the metal salt solution, the doped metal compound is selected from one or more of a compound of copper, a compound of aluminum, a compound of tungsten, a compound of nickel, a compound of magnesium, a compound of titanium, a compound of tin, a compound of molybdenum, a compound of niobium, a compound of europium, a compound of zinc, a compound of manganese, a compound of zirconium, a compound of lithium, a compound of gallium, a compound of lanthanum, and a compound of ytterbium.

11. The method according to claim 10, wherein a molar ratio of the doped metal to the metal salt ranges from 1:19 to 1:4.

12. The method according to claim 11, wherein a doped metal element is doped in the metal oxide nanoparticle of the metal oxide material, the doped metal element is selected from one or more of Cu, Al, Wu, Ni, Mg, Ti, Sn, Mo, Nb, Eu, Zn, Mn, Zr, Li, Ga, La, and Yb, in the metal oxide material, a molar percentage content of the doped metal element ranges from 1% to 30%.

13. A metal oxide material, wherein the metal oxide material comprises a metal oxide nanoparticle and a halogenated ligand connected to a surface of the metal oxide nanoparticle, wherein the halogenated ligand comprises one or both of a halogenated acid ligand and a halogenated alcohol ligand.

14. The metal oxide material according to claim 13, wherein a halogenated acid of the halogenated acid ligand is a halogenated acetic acid, and a halogenated alcohol of the halogenated alcohol ligand is a halogenated ethanol, the halogenated acetic acid is selected from one or more of monochlorinated acetic acid, dichlorinated acetic acid, trichlorinated acetic acid, trifluorinated acetic acid, and tribrominated acetic acid, and the halogenated ethanol is selected from one or more of monochlorinated ethanol, dichlorinated ethanol, trichlorinated ethanol, trifluorinated ethanol, and tribrominated ethanol.

15. The metal oxide material according to claim 13, wherein in the metal oxide material, a content of the halogenated ligand ranges from 10 wt % to 50 wt %.

16. The metal oxide material according to claim 13, wherein the metal oxide nanoparticle is selected from one or more of NiOₓ, VO_{y}, TiO₂, SnO₂, and ZnO, wherein the x is 1 or 1.5, and the y is 1, 1.5, 2 or 2.5.

17. The metal oxide material according to claim 13, wherein a doped metal element is doped in the metal oxide nanoparticle of the metal oxide material, the doped metal element is selected from one or more of Cu, Al, Wu, Ni, Mg, Ti, Sn, Mo, Nb, Eu, Zn, Mn, Zr, Li, Ga, La, and Yb, and a molar percentage content of the doped metal element ranges from 1% to 30%.

18. An optoelectronic device comprising layers of an anode, a light-emitting layer, and a cathode, the optoelectronic device further comprises at least one carrier functional layer, wherein each of the at least one carrier functional layer comprises the metal oxide material according to claim 13.

19. The optoelectronic device according to claim 18, wherein the at least one carrier functional layer is a hole injection layer or a hole transport layer, the hole injection layer or the hole transport layer is disposed between the anode and the light-emitting layer, the metal oxide nanoparticle of the metal oxide material are selected from one or more of NiOₓ, and VO_{y}, wherein the x is 1 or 1.5, and the y is 1, 1.5, 2 or 2.5.

20. The optoelectronic device according to claim 18, wherein the at least one carrier functional layer is an electron transport layer, wherein the electron transport layer is disposed between the cathode and the light-emitting layer, the metal oxide nanoparticle of the metal oxide material is selected from one or more of ZnO, TiO₂, and SnO₂.

21. (canceled)
